(19) United States
(12) Patent Application Publication
(10) Pub. No.: US 2022/0149817 A1
(43) Pub. Date: May 12, 2022

(54) MICRO-ACOUSTIC BANDSTOP FILTER

(71) Applicant: RF360 EUROPE GMBH, Munchen (DE)

(72) Inventor: Edgar SCHMIDHAMMER, Stein an der Traun (DE)

(21) Appl. No.: 17/440,160

(22) PCT Filed: Mar. 27, 2020
(86) PCT No.: PCT/EP2020/058658

§ 371 Date: Sep. 16, 2021

(30) Foreign Application Priority Data
Apr. 4, 2019 (DE) 10 2019 108 852.6

(51) Int. Cl. H03H 9/56; H03H 9/54

(52) U.S. Cl. CPC H03H 9/568; H03H 9/547; H03H 9/542

(57) ABSTRACT

A micro-acoustic bandstop filter comprises a serial inductor (130) coupled between first and second ports (110, 120). A circuit block (140) coupled between the first and second port comprises at least one serial capacitance (141) and at least one shunt capacitance (142), wherein the serial and/or the shunt capacitance is realized by a micro-acoustic resonator (141). A shunt inductor (150) is coupled between the circuit block (140) and a terminal for a reference potential (160).

The present disclosure relates to a micro-acoustic bandstop filter. Specifically, the present disclosure relates to a micro-acoustic bandstop filter that includes first and second ports, serial and shunt inductors and a circuit block comprising serial and shunt capacitances.

### BACKGROUND

Micro-acoustic bandstop filters are used in electronic devices to suppress a specific relatively narrow frequency band to avoid distortion of the processed wanted frequencies by the to-be-suppressed frequency range. Bandstop filters suppressing a very narrow frequency band are often called notch filters.

Bandstop or notch filters may be used in various electronic applications such as automotive or connectivity applications to suppress interfering signals. Bandstop or notch filters may also be used in communication applications such as cellphones or smartphones, for example, to suppress dedicated frequency bands to protect low noise amplifiers, suppress harmonics in carrier aggregation systems to allow proper signal reception or for other functions that require the suppression of a specific frequency or a narrow frequency range.

Conventional notch filters based on LC topologies may have transmission zeroes in the low or zero frequency region and in the high frequency region substantially above the stopband frequency region so that the passband characteristics of conventional LC notch filters have drawbacks for the above-mentioned fields of application. Especially, communication applications for 5G services have usable frequency bands up to 8 GHz so that conventional notch filters may be difficult to use due to their limited passband performance.

It is an object of the present disclosure to provide a bandstop filter that has a deep notch, steep skirts and a low or almost not attenuated passband.

It is another object of the present disclosure to provide a bandstop filter that avoids transmission zeroes in the passband region.

It is yet another object of the present disclosure to provide a bandstop filter that has a substantially uniform performance in the passband region and offers flexibility in the design of the stopband region.

It is yet another object of the present disclosure to provide a bandstop filter arrangement that has more than one bandstop region.

### SUMMARY

One or more of the above-mentioned objects are achieved by a micro-acoustic bandstop filter according to the features of present claim 1.

A bandstop filter according to the principles of the present disclosure includes a serial inductor coupled between first and second input/output ports of the filter and a shunt inductor coupled to a reference potential terminal. A circuit block is connected between the first and second ports that comprises at least one serial capacitance and at least one shunt capacitance. One or more of the serial and shunt capacitances of the circuit block are realized by a respective micro-acoustic resonator. The at least one shunt capacitance of the circuit block is coupled to the shunt inductor.

The above-described circuit structure exhibits allpass characteristics in the passband region outside the bandstop or notch region. Accordingly, no transmission zeroes are included in the passband region, neither at low or zero frequencies nor at high or infinite frequencies. Instead, the passband behavior of the above-described filter structure is rather flat at a low level of insertion loss. Micro-acoustic resonators for the serial or the shunt capacitance or both of the serial and shunt capacitances form a relatively deep attenuation peak having steep skirts to establish the bandstop or notch frequency region.

The circuit block may comprise a ladder-type circuit architecture which includes the at least one serial capacitance and the at least one shunt capacitance of which at least one capacitance is realized as a micro-acoustic resonator. The ladder-type circuit may include more elements in ladder-type arrangement such as a TEE-circuit or a PI-circuit or even a higher order TEE- or PI-circuit. A higher order ladder type arrangement achieves a more defined, narrower stopband region and the number of micro-acoustic resonators used for the serial and shunt capacitances in the ladder-type structure allows to shape and steepen the lower and/or upper skirts of the stopband region. The ladder-type structure for the circuit block allows a relatively flexible design of the stopband behaviour with regard to stopband bandwidth, stopband attenuation level and steepness of the skirts.

According to embodiments, the circuit block can comprise a TEE-circuit which includes a series connection of a first and a second capacitance and a shunt capacitance coupled to the node disposed between the first and second serial capacitances. Depending on circuit requirements, one or more or all of the first, the second and the shunt capacitances can be realized by a respective micro-acoustic resonator. For a TEE-circuit, the shunt inductor is coupled between the shunt capacitance of the TEE-circuit block and the terminal for reference potential.

According to embodiments, the circuit block can comprise a PI-circuit which includes at least one serial capacitance and first and second shunt capacitances coupled to a respective one of the terminals of the serial capacitance. Depending on circuit requirements, one or more or all of the serial, the first and second shunt capacitances of the PI-circuit can be realized by a respective micro-acoustic resonator. For a PI-circuit, the shunt inductor is coupled between the common node of the first and second shunt capacitances and the terminal for reference potential.

The serial inductor coupled between the first and second ports of the bandstop filter primarily transmits those frequencies that are below the stopband region. Consequently, the serial inductor provides a transmission zero at infinite frequency. The serial capacitances of the TEE-circuit block and the serial capacitance of the PI-circuit block primarily transmit those frequencies which are above the stopband region as, in general, a serial capacitor provides a transmission zero at zero frequency. As the capacitor in the shunt path of the TEE- or PI-circuit block has a high impedance for frequencies below the stopband region, there is no transmission happening at low frequencies in this path. As the shunt inductor coupled between the circuit block and the reference potential has a high impedance for frequencies above the stopband region, there is no transmission happening at high, up to infinite, frequencies in this path. Transmission happens when inductor and capacitor are in series resonance thereby forming a low impedance and thus a finite transmission zero (FTZ) located in the stopband of the bandstop filter. Accordingly, the micro-acoustic bandstop or notch filter according to the principles of the present disclosure achieves a relatively strong and defined attenuation in the stopband region and relatively low, flat insertion loss in the passband region outside of the stopband without transmission zeros, in case that parasitics are neglected.

The micro-acoustic resonators that may be used to realize one or more or all of the capacitances of the TEE- or PI-block in the circuit block may be of any type of micro-acoustic or electro-acoustic resonator. These micro-acoustic or electro-acoustic resonators may be surface acoustic wave (SAW) resonators, bulk acoustic wave (BAW) resonators which include solidly-mounted bulk acoustic wave (SMR-BAW) resonators and film bulk acoustic wave (FBAR) resonators. All these resonators comprise a piezoelectric layer to which at least two metal electrodes are attached to generate an acoustic resonating wave by the application of an electrical RF signal to the electrodes. Other resonators such as micro-electro-mechanical-systems (MEMS) resonators are also possible. It is useful to select resonators of the same type to fabricate one of the TEE- and PI-circuit blocks on one single piezoelectric chip.

The circuit block including a TEE- or PI-circuit block may include a higher order TEE- or PI-block. Accordingly, a higher order PI-circuit block may comprise at least two serially-connected capacitances and at least three shunt-connected capacitances wherein one or more or all of said capacitances are realized by a respective micro-acoustic resonator. A higher order TEE-circuit block may comprise at least three serially-connected capacitances and at least two shunt-connected capacitances wherein one or more or all of said capacitances are realized by a respective micro-acoustic resonator. A higher order TEE- and PI-circuit block follows the rules of a ladder-type structure which has a serial capacitance at its both ends and a shunt capacitance at its both ends, respectively.

One or more of the above-mentioned objects are achieved by a micro-acoustic bandstop filter arrangement according to the features of present claim 16.

A micro-acoustic bandstop filter has a good matching so that it can be easily combined with any other RF circuit. Specifically, one micro-acoustic bandstop filter can be connected in series with another micro-acoustic bandstop filter to generate a filter arrangement having a flat passband behaviour and at least two bandstop or notch regions. Even multiple micro-acoustic bandstop filters can be connected serially. Each one of the bandstop or notch filter characteristics can be designed and configured relatively independent from each other to adapt the non-overlapping stopband regions, the stopband bandwidths and the characteristics of the lower and upper stopband skirts to the performance required by the target application. Even more than two stopband regions can be combined within one micro-acoustic bandstop filter arrangement by serially connecting more than two TEE- and/or PI-bandstop filters.

It is to be understood that both the foregoing general description and the following detailed description are merely exemplary, and are intended to provide an overview or framework to understand the nature and character of the claims. The accompanying drawings are included to provide a further understanding and are incorporated in, and constitute a part of, this description. The drawings illustrate one or more embodiments, and together with the description serve to explain principles and operation of the various embodiments. The same elements in different figures of the drawings are denoted by the same reference signs.

### BRIEF DESCRIPTION OF THE DRAWINGS

In the drawings:

FIG. 1 shows a principle block diagram of a micro-acoustic bandstop filter according to the principles of the present disclosure;

FIG. 2 shows a schematic diagram of a micro-acoustic bandstop filter including a PI-circuit;

FIG. 3 shows a schematic diagram of another micro-acoustic bandstop filter including a PI-circuit;

FIG. 4 shows a transmission diagram with transmission curves of various embodiments of micro-acoustic bandstop filters including PI-circuits;

FIG. 5 shows a schematic diagram of a micro-acoustic bandstop filter including a higher order PI-circuit;

FIG. 6 shows a schematic diagram of a micro-acoustic bandstop filter including a TEE-circuit;

FIG. 7 shows a schematic diagram of a micro-acoustic bandstop filter including a higher order TEE-circuit;

FIG. 8 shows a schematic diagram of a micro-acoustic bandstop filter arrangement including a series connection of a TEE- and a PI-bandstop filter;

FIG. 9 shows a transmission diagram including a transmission curve of the circuit of FIG. 8;

FIG. 10 shows a parallel connection of resonators to realize a capacitance of a micro-acoustic bandstop filter;

FIG. 11 shows a serial connection of resonators to realize a capacitance of a micro-acoustic bandstop filter;

FIG. 12 shows a serial and parallel arrangement of resonators to realize a capacitance of a micro-acoustic bandstop filter;

FIG. 13 shows an anti-serial connection of resonators; and

FIG. 14 shows an anti-parallel connection of resonators.

### DETAILED DESCRIPTION OF THE EMBODIMENTS

The present disclosure will now be described more fully hereinafter with reference to the accompanying drawings showing embodiments of the disclosure. The disclosure may, however, be embodied in many different forms and should not be construed as limited to the embodiments set forth herein. Rather, these embodiments are provided so that the disclosure will fully convey the scope of the disclosure to those skilled in the art. The drawings are not necessarily drawn to scale but are configured to clearly illustrate the disclosure.

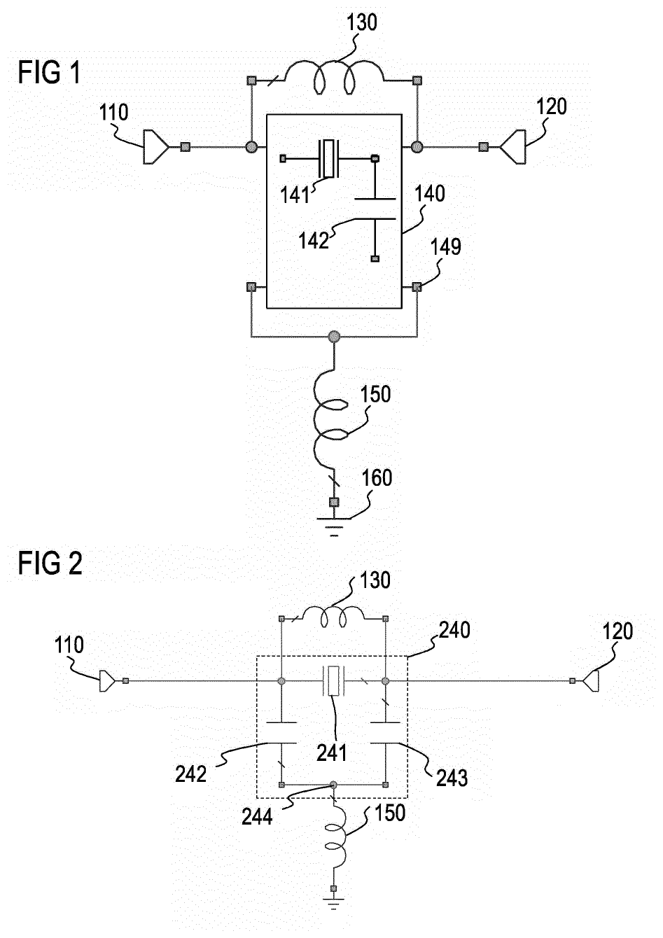

FIG. 1 depicts a principle block diagram of a micro-acoustic bandstop or notch filter according to the principles of the present disclosure. The filter of FIG. 1 comprises a first input/output port 110 and a second output/input port 120. An inductor 130 is connected between ports 110, 120. A circuit block 140 is connected between ports 110, 120, wherein circuit block 140 comprises a shunt terminal 149 which is connected through shunt inductor 150 to ground potential terminal 160. The circuit block 140 includes at least one serial path and at least one shunt path each including a capacitance. At least one of the capacitances such as 141 is realized by a micro-acoustic or electro-acoustic resonator. The other capacitance 142 may be also realized by a micro-acoustic resonator or by a capacitor as depicted in FIG. 1.

Circuit block 140, in general, has a ladder-type structure of one or more series elements such as 141 and one or more shunt elements such as 142. One or more or all of the series and/or shunt elements are realized by a respective micro-acoustic resonator. The concrete form of ladder-type arrangement 140 can be selected by the skilled artisan to fulfill the required RF characteristics of the filter as explained in more detail herein below.

FIG. 2 shows a schematic diagram of an embodiment of the bandstop or notch filter of FIG. 1. The circuit block 240 is realized as a PI-circuit including a series capacitance 241 and shunt capacitances 242, 243 which are connected from one of the terminals of the series capacitance 241 to the shunt inductor 150. The serial capacitance 241 is realized as a micro-acoustic resonator, the shunt capacitances 242, 243 are realized as capacitors. One or more of the shunt capacitances 242, 243 may be, alternatively, realized also as resonators. The node 244 between the shunt capacitances 242, 243 is connected to ground potential by shunt inductor 150.

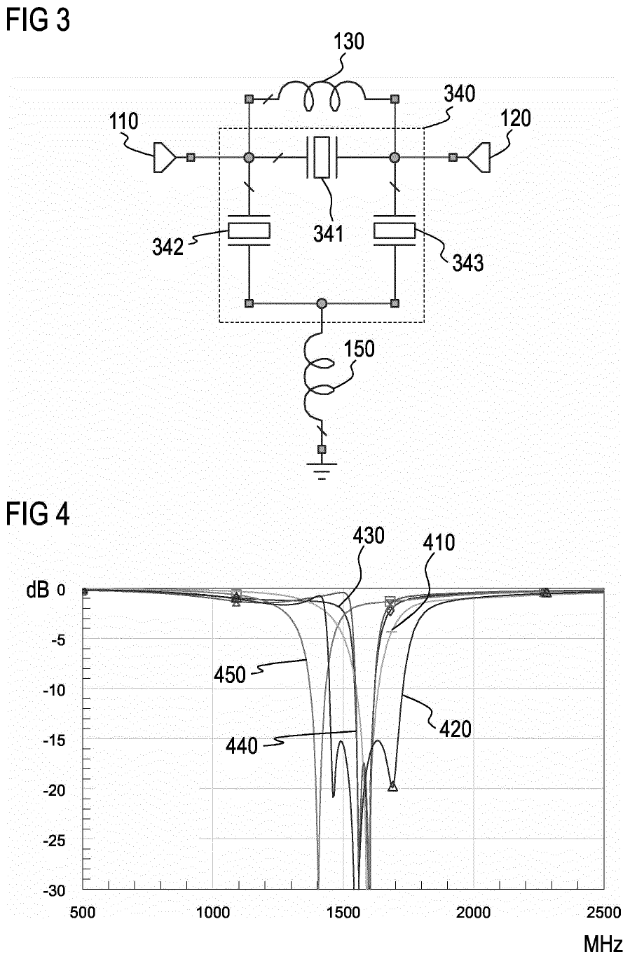

FIG. 3 shows a schematic diagram of another embodiment of the bandstop or notch filter of FIG. 1 wherein the circuit block 340 is configured as a PI-circuit wherein all serial and shunt capacitances are realized as resonators such as resonator 341 connected between ports 110, 120 and resonator 342 connected between port 110 and shunt inductor 150 and resonator 343 connected between port 120 and shunt inductor 150. The resonators may be realized as micro-acoustic resonators.

The resonators such as 141, 241, 341, 342, 343 may be realized as SAW resonators or BAW resonators. BAW resonators may be either SMR-BAW resonators (SMR: solidly mounted resonator) or FBAR resonators (FBAR: film bulk acoustic resonator). Various types of SAW resonators are possible such as HQTCF resonators (HQTCF: high quality temperature compensated filter) or TFSAW resonators (TFSAW: Thin film SAW) or other SAW resonator types. Other resonator concepts such as MEMS resonators are also useful (MEMS: micro-electromechanical systems). The resonators may include a pair of electrodes and a piezoelectric material wherein the electrodes are either disposed on the piezoelectric material or sandwich the piezoelectric material between top and bottom electrodes. A resonating acoustic wave is generated by the application of a RF signal to the electrodes wherein the interaction between electrical RF signal and acoustic resonating signals performs a frequency-selective function on the RF signal thereby achieving a bandstop or notch performance of the RF filter.

Turning now to FIG. 4, several examples of transmission functions of embodiments of bandstop/notch filters are shown. The bandstop/notch filters are configured as PI-circuits such as 240 and 340 including different numbers of resonators and different numbers of capacitors. For example, transmission curve 410 represents a notch filter of which the serial capacitance is realized by a micro-acoustic resonator and the two shunt capacitances are realized by capacitors such as shown in FIG. 2. Transmission curve 420 represents a notch filter of which the serial and the two shunt capacitances are realized by a respective micro-acoustic resonator such as shown in FIG. 3. Curve 430 represents a notch filter of which the serial capacitance and one of the shunt capacitances are realized by a respective micro-acoustic resonator and another one of the shunt capacitances is realized by a capacitor. Curve 440 represents a notch filter of which the serial capacitance is realized by a capacitor and the two shunt capacitances are realized by a respective micro-acoustic resonator. Curve 450 represents a notch filter of which one of the shunt capacitances is realized by a micro-acoustic resonator and another one of the shunt capacitances as well as the serial capacitance are realized by a capacitor.

As can be gathered from FIG. 4, the bandwidth of the stopband frequency region and the steepness of the skirts can be individually determined in that one or more of the capacitances in the PI-circuit block are realized by micro-acoustic resonators or capacitances. In the bandstop or notch frequency region of the transmission characteristics, the attenuation is relatively high so that the signal from input to output is attenuated. In the passband frequency region outside the bandstop region, the attenuation is very low and is rather flat so that the attenuation characteristic of the bandstop filter shows an allpass characteristic outside the bandstop region. Specifically, no high attenuation regions such as transmission zeros are included in the passband region. More specifically, no transmission zeros appear at low or zero frequencies or at high or infinite frequencies, provided that parasitics are neglected. The same principles apply also for a bandstop/notch filter using a TEE-circuit block instead of a PI-circuit block.

FIG. 5 shows a notch filter in which the circuit block 540 is realized by a higher order PI-circuit. Circuit block 540 comprises two serially-connected resonators 541, 542 connected between ports 110, 120. Three shunt-connected resonators 543, 544, 545 are connected between one of the terminals of resonators 541, 542 and the shunt inductor 150. It is to be noted that one or more of the resonators 541, . . . , 545 can be realized with a capacitor instead of a micro-acoustic resonator. Both PI-circuits 340 of FIG. 3 and 540 of FIG. 5 have a ladder-type structure that starts with a shunt element such as 342, 543 and ends with a shunt element such as 343, 545. The higher order PI-element 540 may provide a smaller stopband region compared to the first order PI-element 340. Furthermore, the skirts of the PI-circuit 540 of higher degree may be steeper compared to the skirts of the PI-element 340 of first degree. On the other hand, the level of insertion loss in the passband region outside of the stopband area of the filters including lower and higher order PI-elements of FIGS. 3 and 5 is, to the most extent, similar to each other.

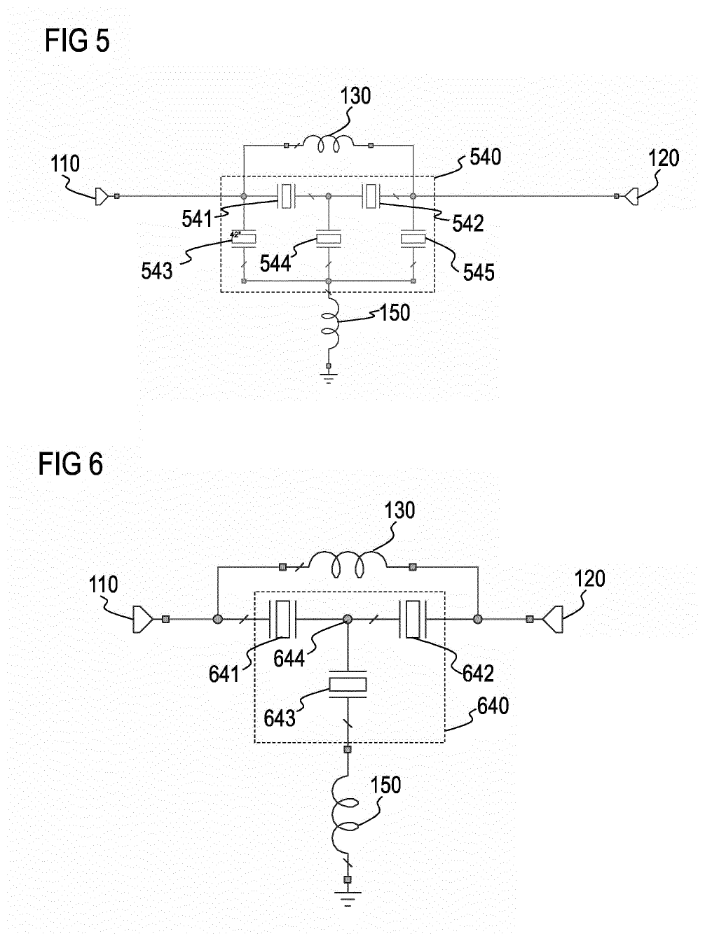

FIG. 6 shows a schematic diagram of another embodiment of a micro-acoustic bandstop or notch filter which includes a TEE-circuit block 640 connected between ports 110, 120 and shunt inductor 150. The TEE-circuit block 640 comprises a serial connection of capacitances 641, 642 and a shunt-connected capacitance 643 coupled between the node 644 between capacitances 641, 642 and shunt inductor 150. All three capacitances 641, 642, 643 are realized as micro-acoustic resonators such as a SAW or BAW or MEMS resonators as explained above.

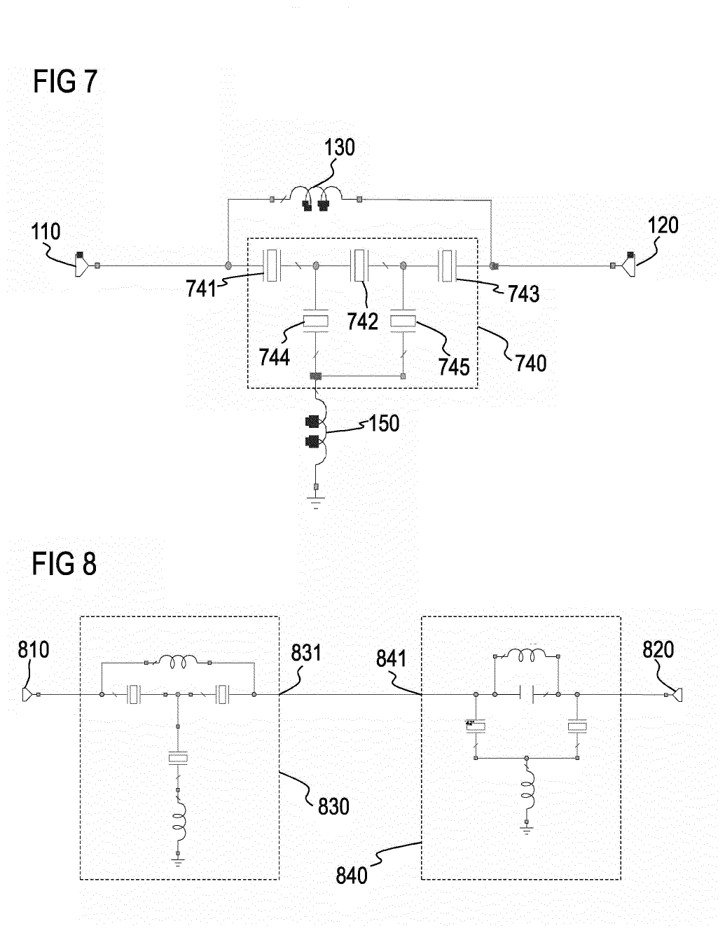

FIG. 7 shows a schematic diagram of an embodiment of a notch filter in which the circuit block 740 is realized by a higher order TEE-circuit. Circuit block 740 comprises three serially-connected resonators 741, 742, 743 connected between ports 110, 120. Two shunt-connected resonators 744, 745 are connected between the nodes between resonators 741, 742 and between resonators 742, 743 and the shunt inductor 150. Although all resonators 741, . . . , 745 of the filter depicted in FIG. 7 are realized by micro-acoustic resonators, it is also possible that one or more of the resonators 741, . . . , 745 are realized with a capacitor instead of a micro-acoustic resonator.

Both TEE-circuits 640 of FIG. 6 and 740 of FIG. 7 have a ladder-type structure that starts with a serial element such as 641, 741 and ends with a serial element such as 642, 743. The higher order TEE-element 740 may provide a smaller stopband region compared to the first order TEE-element 640. Furthermore, the skirts of the TEE-circuit 740 of higher degree may be steeper compared to the skirts of the TEE-element 640 of first degree, wherein the level of insertion loss in the passband region outside of the stopband area of the filters including lower and higher order TEE-elements is, to the most extent, similar to each other. PI- and TEE-circuits of even higher degree are also possible in bandstop/notch filters.

The use of a PI-circuit in the micro-acoustic bandstop/notch filter such as shown in FIGS. 2 and 3 may have a relatively steep lower, left skirt compared to the upper, right skirt which appears weaker than the steep lower skirt. The use of a TEE-circuit in the micro-acoustic bandstop/notch filter such as is shown in FIG. 6 leads to a stopband behaviour which has a relatively steep upper, right skirt of the stopband region and a relatively weak lower, left skirt. During circuit design, the choice between PI- and TEE-circuits may depend on the nearby passband requirements below or above the notch frequency region. For example, if the upper skirt should be steep to achieve a defined upper skirt notch behaviour when a low insertion loss is required just above the notch, a TEE-circuit may be selected. If the lower skirt should be steep to achieve a low insertion loss just below the stopband, a PI-circuit may be selected.

FIG. 8 shows a serial connection of two micro-acoustic bandstop/notch filters 830, 840. Bandstop filter 830 includes a TEE-circuit and is connected to port 810. Bandstop filter 840 includes a PI-circuit and is connected to port 810 and to bandstop filter 830. One port of filter 830 such as port 831 is connected to one port of filter 840 such as port 841, wherein the other ports of filters 830, 840 are connected to input/output ports 810 and 820, resp. As filters 830, 840 each exhibit an allpass characteristic, it is possible to serially connect two or more of said bandstop/notch filters to achieve two or more bandstop frequency regions wherein the passband regions are substantially maintained with relatively low insertion loss.

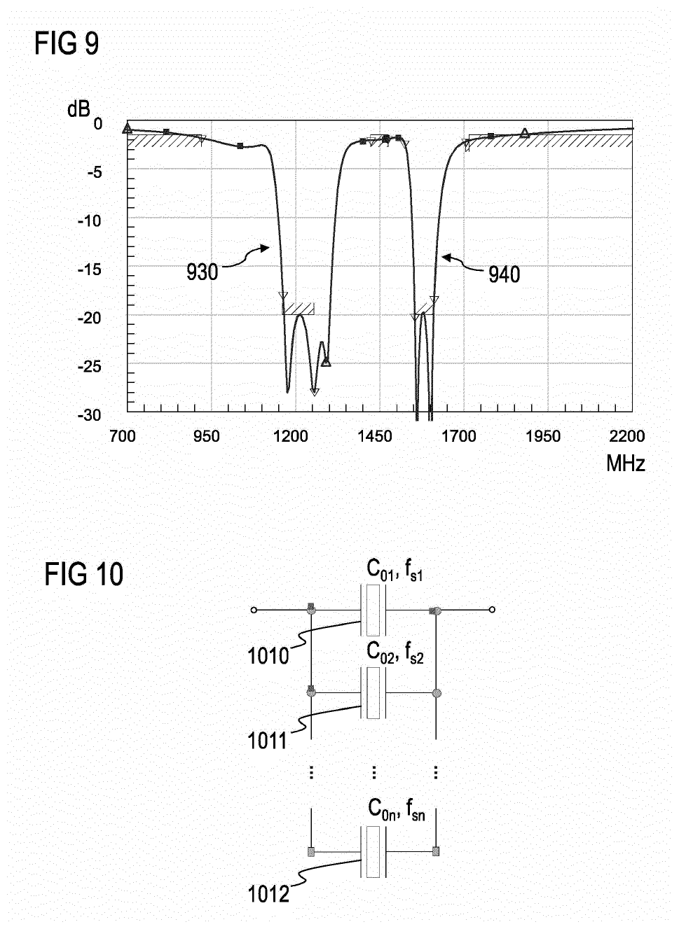

FIG. 9 shows a transmission diagram depicting the transmission characteristic of the filter of concatenated bandstop/notch filters 830, 840 of FIG. 8. The transmission curve of FIG. 9 includes a relatively wide bandstop region 930 which originates from TEE-circuit bandstop filter 830. The transmission curve includes further a relatively narrow bandstop region 940 which originates from PI-bandstop filter 840. Filter 830 includes two serial resonators and one shunt resonator connected in TEE-fashion, and bandstop filter 840 includes two shunt resonators and one serial capacitor connected in PI-fashion. The shape and the width of the bandstop regions can be configured substantially independently from each other applying the principles discussed above such as varying the number of micro-acoustic resonators vs. the number of capacitors and selecting first or higher order TEE- or PI-circuits. The nearby passband requirements are achieved using both TEE- and PI-circuit approaches. The out-of-band passband performance does not show a degradation caused by capacitive or inductive effects in the absence of parasitics.

FIG. 10 shows a parallel connection of micro-acoustic resonators that can be used to realize one or more of the capacitances in the above described bandstop/notch filters to further improve the bandstop behaviour. Instead of a single resonator a parallel-connected sequence of resonators can be used. The parallel-connected sequence of resonators comprises resonators 1010, 1011, 1012 connected in parallel to each other. Although three resonators are depicted, it is possible to use two or more up to a number of n resonators connected in parallel. Each of the n parallel connected resonators 1010, 1011, 1012 can have different static capacitances Cₒⱼ and different series resonance frequencies fₛⱼ (with j=1, . . . , n) and also different capacitance ratios between mechanical capacitance Cₘⱼ and static capacitance Cₒⱼ (with j=1, . . . , n).

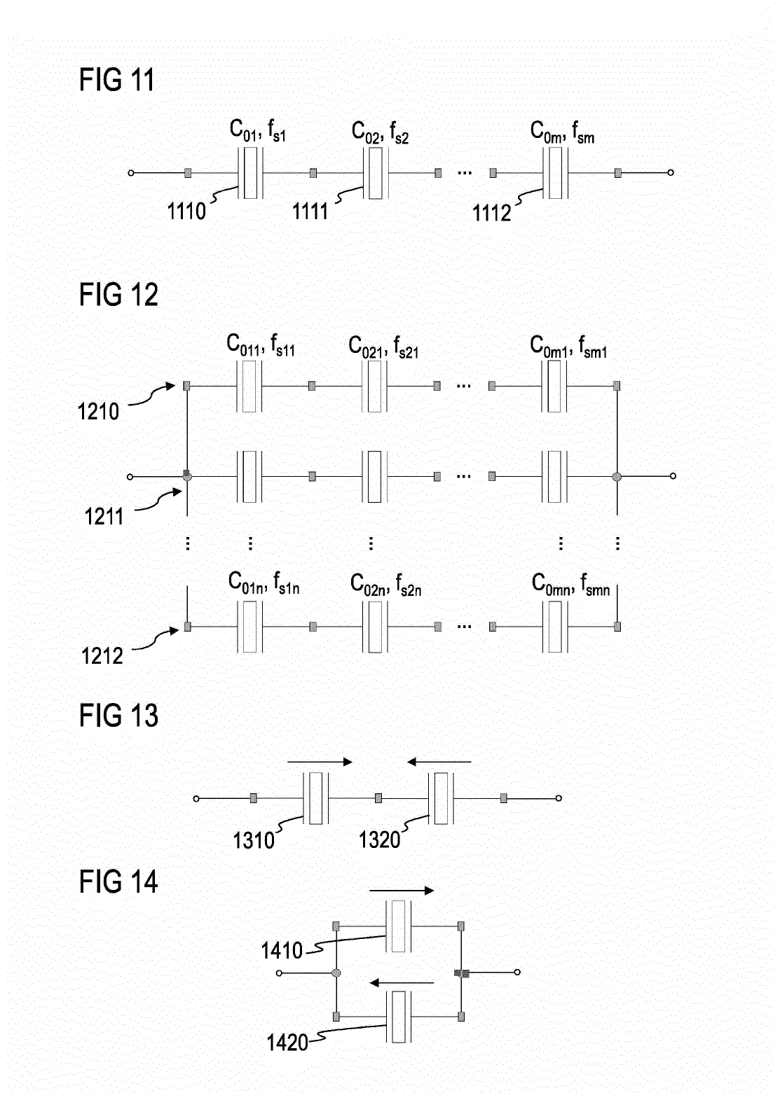

FIG. 11 shows a serial connection of micro-acoustic resonators that can be used to realize one or more of the capacitances in the above described bandstop/notch filters to further improve the bandstop behaviour. Instead of a single resonator a sequence of m serially connected resonators can be used. The serially connected sequence of resonators comprises resonators 1110, 1111, 1112 connected in series with each other. Although three resonators are depicted, it is possible to use two or more up to a number of m resonators connected in series. Each of the m serially connected resonators 1110, 1111, 1112 can have different static capacitances Cₒᵢ and different series resonance frequencies fₛᵢ (with i=1, . . . , m) and also different capacitance ratios between mechanical capacitance Cₘᵢ and static capacitance Cₒᵢ (with i=1, . . . , m).

The difference in the mentioned parameters is optional so that two or more resonators may have the same parameter values and may be realized as identical resonators depending on the circuit requirements and circuit specifications to be achieved. This includes that all parallel or serially connected resonators may be realized identically. For example, in a realization of a notch filter with 5 resonators, 3 resonators may be realized identically and 2 resonators may be realized with different parameters such as one or more of mechanical capacitance, static capacitance and series resonance frequency.

FIG. 12 shows a combination of serially and parallel connected micro-acoustic resonators. Such a serial and parallel array of resonators may be used to realize one or more of the capacitances in the above described bandstop/notch filters. The array comprises a parallel connection of two or more serial connections 1210, 1211, 1212 of resonators. Two or more or each of the resonators depicted in FIG. 12 can have different static capacitances Cₒᵢⱼ and different series resonance frequencies fₛᵢⱼ (with i=1, . . . , m and j=1, . . . , n) and also different capacitance ratios between mechanical capacitance Cₘᵢⱼ and static capacitance Cₒᵢⱼ. This option includes that parameters may also be the same.

FIG. 13 shows an anti-serial connection of resonators that can be used to realize any of the above mentioned capacitances or to replace any of the above-mentioned resonators. The anti-serial connection of resonators has improved linearity to improve performance of the notch filter. Resonators 1310, 1320 are connected serially, wherein the polarity of the crystal axis of the piezoelectric material included in said resonators has anti-serial orientation depicted with corresponding arrows. The arrow of resonator 1310 shows from left to right, the arrow of resonator 1320 shows from right to left, that is in opposite direction when compared to resonator 1310. In practice, the opposite polarity orientation of the piezoelectric material can be selected, for example, during the fabrication of said resonators or by layout modifications. The electric field or voltage is either in direction or opposite to the e.g. crystal axis of a piezoelectric material resulting in a different vibration behaviour at a given voltage or current.

FIG. 14 shows an anti-parallel connection of resonators that can be used to realize any of the above mentioned capacitances or to replace any of the above-mentioned resonators. The anti-parallel connection of resonators has improved linearity to improve performance of the notch filter. Resonators 1410, 1420 are connected in parallel to each other wherein the polarity of the crystal axis of the piezoelectric material included in said resonators has anti-parallel orientation depicted with corresponding arrows.

It will be apparent to those skilled in the art that various modifications and variations can be made without departing from the spirit or scope of the disclosure as laid down in the appended claims. Since modifications, combinations, sub-combinations and variations of the disclosed embodiments incorporating the spirit and substance of the disclosure may occur to the persons skilled in the art, the disclosure should be construed to include everything within the scope of the appended claims.

1. A micro-acoustic bandstop filter, comprising:
a first port and a second port;
a serial inductor coupled between the first and the second ports;
a circuit block coupled to the first and second ports and comprising at least one serial capacitance and at least one shunt capacitance, the at least one serial capacitance and/or the at least one shunt capacitance realized by a micro-acoustic resonator; and
a shunt inductor coupled between the circuit block and a terminal for a reference potential.

2. The micro-acoustic bandstop filter according to claim 1, wherein the circuit block comprises a laddertype circuit including the at least one serial capacitance and at least one shunt capacitance.

3. The micro-acoustic bandstop filter according to claim 1, wherein the circuit block comprises a TEE-circuit including a serial connection of a first and a second capacitance and a shunt capacitance coupled to the node disposed between the first and second capacitances, wherein one or more of the first, the second and the shunt capacitances is realized by a respective micro-acoustic resonator.

4. The micro-acoustic bandstop filter according to claim 3, wherein the shunt inductor is coupled between the shunt capacitance and the terminal for a reference potential.

5. The micro-acoustic bandstop filter according to claim 1, wherein the circuit block comprises a PI-circuit including at least one serial capacitance and a first shunt capacitance coupled to a terminal of the at least one serial capacitance and a second shunt capacitance coupled to another terminal of the at least one serial capacitance, one or more of the at least one serial and the first and second shunt capacitances realized by a respective micro-acoustic resonator.

6. The micro-acoustic bandstop filter according to claim 5,
wherein the shunt inductor is coupled between the node between the first and second shunt capacitances and the terminal for a reference potential.

7. The micro-acoustic bandstop filter according to claim 1, wherein each one of the serial and/or shunt capacitances is realized by a micro-acoustic resonator.

8. The micro-acoustic bandstop filter according to claim 7,
wherein the micro-acoustic resonators are selected from surface acoustic wave resonators, bulk acoustic wave resonators, film bulk acoustic wave resonators and micro-electromechanical systems resonators.

9. The micro-acoustic bandstop filter according to claim 1, wherein the circuit block comprises at least two serially connected capacitances and at least three shunt connected capacitances, wherein the at least three shunt connected capacitances are connected to one of the terminals of the at least two serially connected capacitances and to the shunt inductor and wherein one or more or all of said capacitances are realized by a respective micro-acoustic resonator.

10. The micro-acoustic bandstop filter according to claim 1, wherein the circuit block comprises at least three serially connected capacitances and at least two shunt connected capacitances, wherein the at least two shunt connected capacitances are connected to one of the nodes between two of the at least three serially connected capacitances and to the shunt inductor and wherein one or more or all of said capacitances are realized by a respective micro-acoustic resonator.

11. The micro-acoustic bandstop filter according to claim 1, comprising:
a first micro-acoustic resonator connected to the first port;
a second micro-acoustic resonator connected to the first micro-acoustic resonator and to the second port; and
a third micro-acoustic resonator connected to the first and second micro-acoustic resonators and the shunt inductor;
wherein the serial inductor connected in parallel to the serial connection of the first and second micro-acoustic resonators.

12. The micro-acoustic bandstop filter according to claim 1, comprising:
a first micro-acoustic resonator connected between the first and second ports (110, 120);
a second micro-acoustic resonator connected between the first port and the shunt inductor; and
a third micro-acoustic resonator connected between the second port and the shunt inductor, wherein
the serial inductor is connected in parallel to the first micro-acoustic resonator.

13. The micro-acoustic bandstop filter according to claim 1, wherein the at least one serial capacitance and/or the at least one shunt capacitance is realized by a serial connection of two or more micro-acoustic resonators or a serial connection of two or more micro-acoustic resonators or a parallel connection of two or more serial connections of two or more micro-acoustic resonators.

14. The micro-acoustic bandstop filter according to claim 13, wherein the two or more micro-acoustic resonators have different static capacitances (C₀ₙ, C₀ₘ, C₀ₘₙ) and/or different resonance frequencies (fₛₙ, fₛₘ, fₛₘₙ).

15. The micro-acoustic bandstop filter according to claim 1, wherein the at least one serial capacitance and/or the at least one shunt capacitance is realized by an anti-serial connection at least two micro-acoustic resonators or an anti-parallel connection of two or more micro-acoustic resonators.

16. The micro-acoustic bandstop filter according to claim 1, comprising a first micro-acoustic bandstop filter and a second micro-acoustic bandstop filter connected serially to the first micro-acoustic bandstop filter, wherein at least one port of the first micro-acoustic bandstop filter is connected to at least one port of the second micro-acoustic bandstop filter.

17. The micro-acoustic bandstop filter according to claim 16, the first micro-acoustic bandstop filter having a first bandstop frequency region and the second micro-acoustic bandstop filter having a second bandstop frequency region, wherein the first bandstop frequency region and the second bandstop frequency region are non-overlapping.
